(19) United States
(12) Patent Application Publication
(10) Pub. No.: US 2024/0114754 A1
(43) Pub. Date: Apr. 4, 2024

(54) DISPLAY DEVICE AND METHOD FOR MANUFACTURING THE SAME

(71) Applicant: SAMSUNG DISPLAY CO., LTD., Yongin-si (KR)

(72) Inventors: CHANGYEONG SONG, Yongin-si (KR); Yeonguk Kim, Yongin-si (KR); Jongwoo Kim, Yongin-si (KR); Heeyeon Park, Yongin-si (KR); Yongchan Ju, Yongin=si (KR); Jaeheung Ha, yongin-si (KR)

(21) Appl. No.: 18/467,813

(22) Filed: Sep. 15, 2023

(30) Foreign Application Priority Data
Sep. 16, 2022 (KR) 10-2022-0116927

(51) Int. Cl. H10K 59/80; H10K 59/65; H10K 71/13

(52) U.S. Cl. CPC H10K 59/879; H10K 59/65; H10K 71/135

(57) ABSTRACT

A display device includes a first substrate including a first region and a second region surrounding the first region in a plan view, a first filler disposed on the first substrate and overlapping the first region, a second filler disposed on the first substrate and overlapping the second region, and including a material different from the first filler, and a second substrate disposed on the first filler and the second filler.

### CROSS-REFERENCE TO RELATED APPLICATION(S)

This application claims priority under 35 U.S.C. § 119 to Korean Patent Application No. 10-2022-0116927, filed on Sep. 16, 2022 in the Korean Intellectual Property Office KIPO, the disclosure of which is hereby incorporated by reference in its entirety.

### TECHNICAL FIELD

Embodiments of the present inventive concept relate to a display device and a method of manufacturing the display device. More particularly, embodiments of the present disclosure relate to a display device including a camera and a method of manufacturing the display device.

### DISCUSSION OF RELATED ART

As information technology develops, the importance of display devices, which are a primary communication media between users and information, is being heightened. Accordingly, the use of display devices, such as liquid crystal display devices, organic light emitting display devices, plasma display devices, and the like, is increasing.

In a case where a device includes both a display device and a camera, an aspect ratio (that is, a screen-to-body ratio, STBR) of the display device may be impacted by the need to arrange the camera in a same area. Different approaches to improving the aspect ratio of display devices have been developed. In one example, a technique of forming a hole for arranging a camera in a display area of a display panel of a portable electronic device has been developed. In another example, a technique for arranging the camera under the display panel has also been developed.

In these techniques, the ability of the camera to capture a clear image may be affected.

### SUMMARY

Embodiments of the present disclosure may provide a display device that enables clear imaging, for example, preventing the blurring of images.

Embodiments of the present disclosure may provide a method of manufacturing the display device.

A display device according to embodiments of the present disclosure may include a first substrate, a first filler, a second filler, and a second substrate. The first substrate may include a first region and a second region surrounding the first region. The first filler may be disposed on the first substrate and may overlap the first region. The second filler may be disposed on the first substrate may overlap the second region, and may include a material different from the first filler. The second substrate may be disposed on the first filler and the second filler.

In an embodiment, a refractive index of the first filler and a refractive index of the second filler may be different from each other.

In an embodiment, a refractive index of the first filler may be greater than a refractive index of the second filler.

In an embodiment, a refractive index of the first filler may be between about 1.48 and about 1.52.

In an embodiment, a refractive index of the second filler may be less than or equal to about 1.45.

In an embodiment, the display device may further include a camera overlapping the first region and the first filler.

In an embodiment, the first filler may include a siloxane backbone, and the siloxane backbone may be connected to at least one phenyl group.

In an embodiment, the second filler may include a siloxane backbone. The siloxane backbone may be connected to at least one methyl group.

A display device according to embodiments of the present disclosure may include a first substrate, a camera, a filler layer, and a second substrate. The first substrate may include a light emitting element, a first region and a second region. The second region may surround the first region. The camera may overlap the first region in a plan view. The filler layer may be disposed on the first substrate, and may include a first filler and a second filler. The first filler may overlap the first region, and the second filler may overlap the second region. The second filler may have a refractive index less than a refractive index of the first filler. The second substrate may be disposed on the filler layer.

In an embodiment, a difference between the refractive index of the first filler and the refractive index of the second filler may be less than or equal to about 0.2.

In an embodiment, the first filler may overlap the camera in the plan view.

In an embodiment, the refractive index of the second filler may be less than or equal to about 1.45.

A method of manufacturing a display device according to embodiments of the present disclosure may include forming a first substrate including a first region and a second region surrounding the first region in a plan view, forming a first filler, overlapping the first region, on a second substrate facing the first substrate, and forming a second filler overlapping the second region on the second substrate and formed of a material different from the first filler.

In an embodiment, the first filler may be formed by at least one of a jet dispenser method, an inkjet method, or a one drop filling method and the second filler may be formed by at least one of the jet dispenser method, the inkjet method, or the one drop filling method.

In an embodiment, the forming of the first filler and the forming of the second filler may be separately performed.

In an embodiment, the method may further include bonding the first substrate and the second substrate with the first filler and the second filler interposed therebetween, and curing the first filler and the second filler.

In an embodiment, the first filler and the second filler may be cured by one of a thermal curing method, an ultraviolet curing method, or a thermal and UV curing method.

In an embodiment, a temperature of the thermal curing method may be less than or equal to about 100° C.

In an embodiment, the method may further include arranging a camera in the first region.

As describe above, the display device according to embodiments of the present disclosure may include a first substrate, a first filler, a second filler and a second substrate. The first substrate may include a first region and a second region surrounding the first region in a plan view. The first filler may be disposed on the first substrate and may overlap the first region. The second filler may be disposed on the first substrate, may overlap the second region, may be disposed on a same layer as the first filler, and may include a material different from the first filler. The second substrate may be disposed on the first filler and the second filler. As the first region overlaps the first region, and the second filler overlaps the second region, the first filler and the second filler may prevent a blurring of images due to an optical path difference and may reduce a decrease in light efficiency.

In addition, as each of the first filler and the second filler includes a siloxane backbone, the first filler and the second filler may prevent an occurrence of haze due to a use of different materials.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1.

FIG. 3 is a cross-sectional view taken along line of FIG. 1.

FIG. 4 is an enlarged view of region A in FIG. 3.

FIG. 5 is a flowchart of a method of manufacturing the display device according to an embodiment of the present disclosure.

FIGS. 6, 7, 8, 9, 10, 11, 12, and 13 are views for illustrating the method of manufacturing the display device of FIG. 5.

FIG. 14 is a view for illustrating a display device according to another embodiment.

### DETAILED DESCRIPTION

Hereinafter, embodiments of the present disclosure will be described in more detail with reference to the accompanying drawings. The same reference numerals are used for the same components in the drawings, and redundant descriptions of the same components may be omitted.

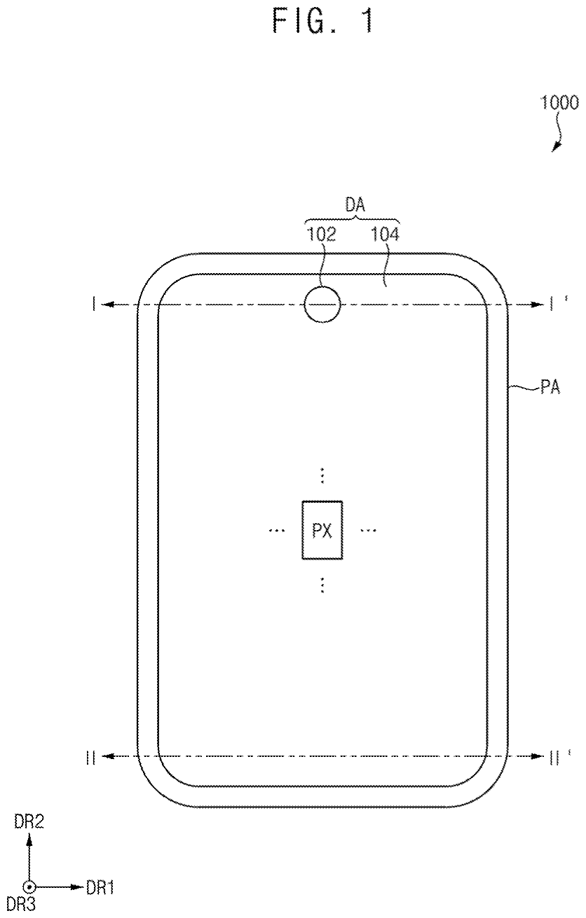

FIG. 1 is a plan view illustrating a display device according to an embodiment of the present disclosure.

Referring to FIG. 1, a display device 1000 according to an embodiment of the present disclosure may include a display area DA and a peripheral area PA.

The peripheral area PA may be an area not capable of displaying an image. Also, the peripheral area PA may surround at least a portion of the display area DA. For example, the peripheral area PA may entirely surround the display area DA.

The display area DA may be an area capable of displaying the image. To display the image, the display area DA may generate light or may adjust a transmittance of light provided from an external light source, for example.

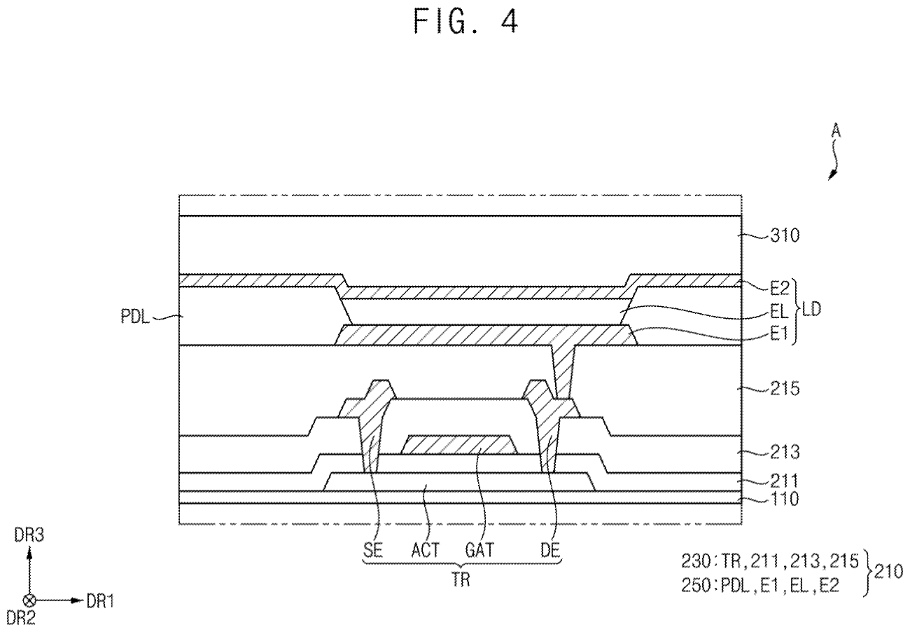

A plurality of pixels PX may be arranged in the display area DA. For example, each of the plurality of pixels PX may include a driving element and a light emitting element (e.g., a light emitting element LD of FIG. 4).

Each of the plurality of pixels PX may display a predetermined color. For example, each of the plurality of pixels PX may display a red color, a green color, or a blue color. That is, each of the plurality of pixels PX may be a minimum unit capable of independently displaying a color.

The plurality of pixels PX may be arranged in a matrix form along a first direction DR1 and a second direction DR2 crossing the first direction DR1. For example, the first direction DR1 and the second direction DR2 may be perpendicular to each other. That is, the plurality of pixels PX may be arranged in a plane defined by the first direction DR1 and the second direction DR2.

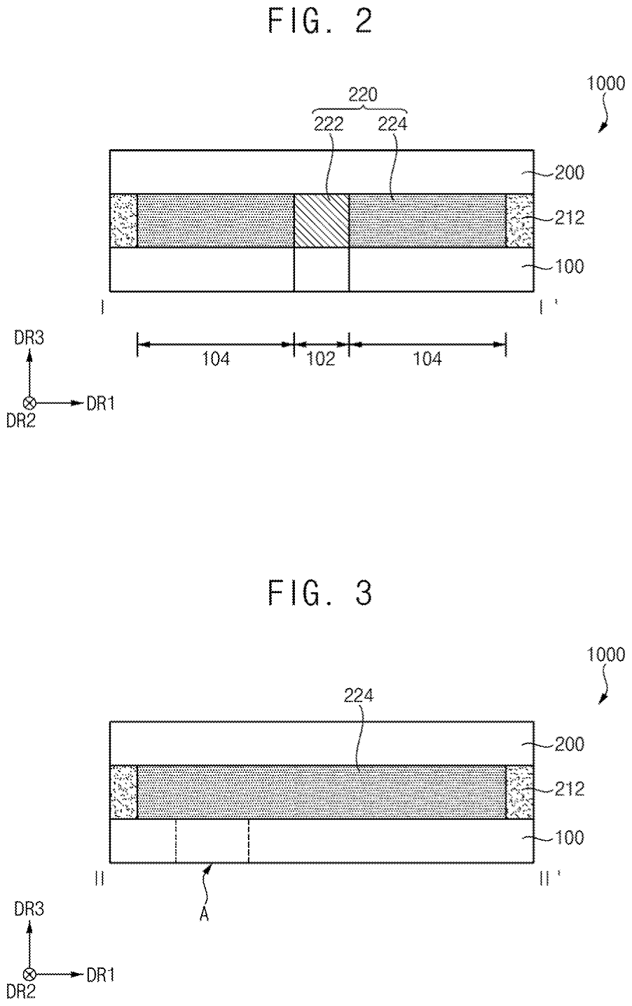

The display area DA may include a first region 102 and a second region 104. A detailed description of the first region 102 and the second region 104 will be described later with reference to FIGS. 2 to 4.

FIG. 2 is a cross-sectional view taken along line I-I′ of FIG. 1, FIG. 3 is a cross-sectional view taken along line of FIG. 1, and FIG. 4 is an enlarged view of region Ain FIG. 3.

Referring to FIGS. 2 and 3, the display device 1000 according to an embodiment of the present disclosure may include a first substrate 100, a filler layer 220, a cell seal 212, and a second substrate 200.

Referring to FIG. 4, the region A of the first substrate 100 may include a base substrate 110, a display element layer 210, and a capping layer 310. The remaining portions of the first substrate 100 may be substantially similar to region A.

The base substrate 110 may include a transparent material or an opaque material. For example, the base substrate 110 may include quartz, synthetic quartz, calcium fluoride, F-doped quartz, soda lime, non-alkali glass, and the like. These may be used alone or in combination with each other. The base substrate 110 may be made of a transparent resin substrate. An example of the transparent resin substrate may be a polyimide substrate. The base substrate 110 may not be limited these example materials and other materials may be used.

A buffer layer may be further disposed between the base substrate 110 and the display element layer 210. The buffer layer may prevent diffusion of metal atoms or impurities from the base substrate 110 into an active layer ACT.

The display element layer 210 may be disposed on the base substrate 110. The display element layer 210 may include a circuit element layer 230 and a light emitting element layer 250.

The circuit element layer 230 may be disposed on the base substrate 110. The circuit element layer 230 may include insulating layers and conductive layers. Specifically, the circuit element layer 230 may include at least one transistor TR, a first insulating layer 211, a second insulating layer 213, and a third insulating layer 215. The transistor TR may include the active layer ACT, a gate electrode GAT, a source electrode SE, and a drain electrode DE. Elements included in the circuit element layer 230 may drive the light emitting element included in the light emitting element layer 250.

The active layer ACT may be disposed on the base substrate 110. The active layer ACT may include a source region and a drain region, wherein the source region and the drain region may each be doped with impurities, and a channel region disposed between the source region and the drain region.

The first insulating layer 211 may be disposed on the active layer ACT. The first insulating layer 211 may cover the active layer ACT. In an embodiment, the first insulating layer 211 may be formed of an inorganic material. Accordingly, the first insulating layer 211 may be formed to have substantially a same thickness as the active layer ACT.

The second insulating layer 213 may be disposed on the first insulating layer 211. The second insulating layer 213 may cover the gate electrode GAT. The gate electrode GAT may be formed on the first insulating layer 211. In an embodiment, the second insulating layer 213 may be formed of an inorganic material. Accordingly, the second insulating layer 213 may be formed to have substantially a same thickness as the gate electrode GAT.

The source electrode SE and the drain electrode DE may be disposed on the second insulating layer 213. The source electrode SE may contact the source region of the active layer ACT through a first contact hole formed through the first insulating layer 211 and the second insulating layer 213. The drain electrode DE may contact the drain region of the active layer ACT through a second contact hole formed through the first insulating layer 211 and the second insulating layer 213.

The third insulating layer 215 may be disposed on the second insulating layer 213. The third insulating layer 215 may cover the source electrode SE and the drain electrode DE. In an embodiment, the third insulating layer 215 may be formed of an organic material. Accordingly, an upper surface of the third insulating layer 215 may be substantially flat.

The light emitting element layer 250 may be disposed on the circuit element layer 230. The light emitting element layer 250 may include a pixel defining layer PDL and the light emitting element LD. The light emitting element LD may include a first electrode E1, a light emitting layer EL, and a second electrode E2. The light emitting element layer 250 may emit light.

The first electrode E1 may be disposed on the third insulating layer 215. The first electrode E1 may be reflective or have a property of light transmittance. In an embodiment, the first electrode E1 may include a metal material. Herein, light transmittance may be understood as a property that measures an amount or percentage of incident light that may pass through a material.

The pixel defining layer PDL may be disposed on the third insulating layer 215. An opening exposing an upper surface of the first electrode E1 may be formed in the pixel defining layer PDL. In an embodiment, the pixel defining layer PDL may include an organic material or an inorganic material.

The light emitting layer EL may be disposed on the first electrode E1. Specifically, the light emitting layer EL may be disposed in the opening formed in the pixel defining layer PDL. The light emitting layer EL may have a multi-layer structure including, for example, a hole injection layer, a hole transport layer, an organic emission layer, an electron transport layer, and an electron injection layer.

In an embodiment, the organic emission layer of the light emitting layer EL may include one or more light emitting materials. The light emitting materials may be capable of emitting different color lights according to sub-pixels (e.g., the plurality of pixels PX in FIG. 1). For example, the organic emission layer may include a first light emitting material capable of emitting red color light, a second light emitting material capable of emitting green color light, and a third light emitting material capable of emitting blue color light.

In another embodiment, the organic emission layer may emit white light, for example, by stacking a plurality of light emitting materials capable of generating different color lights such as red light, green light, and blue light. In this case, a color filter may be further disposed on the organic emission layer. The color filter may include at least one of a red color filter, a green color filter, or a blue color filter.

The second electrode E2 may be disposed on the light emitting layer EL. In an embodiment, the second electrode E2 may have a plate shape. That is, the second electrode E2 may have a recessed portion and an elevated peripheral portion surrounding, or partially surrounding, the recessed portion. The second electrode E2 may have a property of light transmittance. The second electrode E2 may be a reflective metal material.

The capping layer 310 may be disposed on the display element layer 210. Specifically, the capping layer 310 may be disposed on the light emitting element layer 250. The capping layer 310 may protect the light emitting layer EL.

The capping layer 310 may include an organic insulating material or an inorganic insulating material. For example, the capping layer 310 may include triamine derivatives, arylenediamine derivatives, 4,4′-N,N′ triamine derivatives, arylenediamine derivatives, 4,4′-N,N′-dicarbazole-biphenyl, tris-8-hydroxyquinoline aluminum, and the like. These may be used alone or in combination with each other. The capping layer 310 may not be limited to these example materials and other materials may be used.

As shown in FIGS. 1, 2 and 3, as the display device 1000 may include the display area DA and the peripheral area PA, and the first substrate 100 may include the display area DA and the peripheral area PA.

The display area DA may include the first region 102 and the second region 104. The second region 104 may surround the first region 102. That is, the first region 102 may be located inside and the second region 104 may be located outside, in the plan view.

Each of the first region 102 and the second region 104 may have a rectangular shape with rounded corners. Alternatively, each of the first region 102 and the second region 104 may have a circular shape. The first region 102 and the second region 104 may not be limited to these examples, and the first region 102 and the second region 104 may have various shapes such as a square, a triangle, and the like. The first region 102 and the second region 104 may have different shapes.

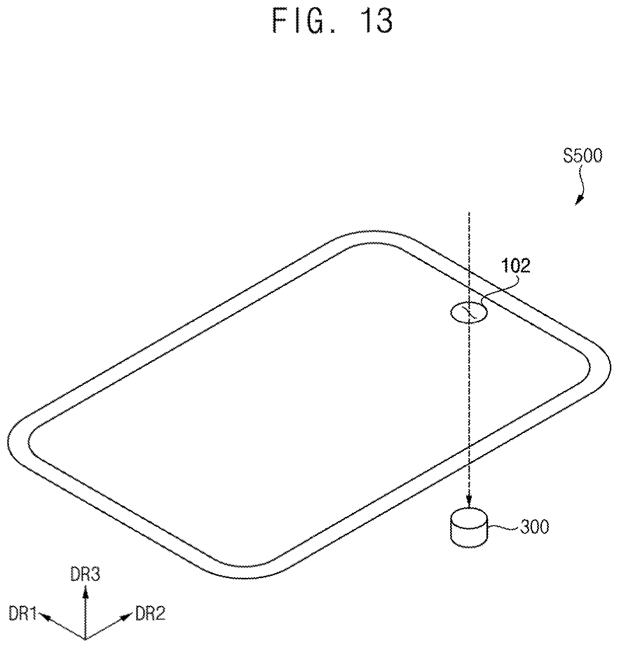

The first region 102 may overlap a functional module. Specifically, the first region 102 may overlap a camera (e.g., a camera 300 of FIG. 13), in the plan view. In an embodiment, the camera 300 may be disposed in a hole formed in the first region 102 of the first substrate 100. In another embodiment, the camera 300 may be disposed below the first substrate 100. The camera 300 may be disposed partially in the hole and partially below the first substrate 100. Furthermore, it should be understood that that the display device 1000 may be manufactured before the camera 300 is arranged in the first region 102 (e.g., see FIG. 13).

The functional module may be a module capable of helping a user to perform various functions using the display device 1000. For example, the functional module may include a camera module, a face recognition sensor module, a pupil recognition sensor module, an acceleration sensor module, a proximity sensor module, an infrared sensor module, an illuminance sensor module, and the like. The camera module may be a module that captures (or recognizes) an image of an object located in front of the display device 1000. The face recognition sensor module may be a module that detects a user's face. The pupil recognition sensor module may be a module that detects a pupil of the user. The acceleration sensor module and a geomagnetic sensor module may be modules that determine a movement of the display device 1000. The proximity sensor module and the infrared sensor module may be modules that detect proximity of the front of the display device 1000. The illuminance sensor module may be a module that measures a degree of external brightness. The functional module is not limited to these examples, and other devices may be implemented.

The filler layer 220 may be disposed on the first substrate 100. Specifically, the filler layer 220 may be disposed on the capping layer (e.g., the capping layer 310 of FIG. 4). The filler layer 220 may include a first filler 222 and a second filler 224. In other words, the first filler 222 and the second filler 224 may be disposed on a same layer as shown in FIG. 2.

In an embodiment, the first filler 222 may overlap the first region 102. The first region 102 may overlap the camera (e.g., the camera 300 of FIG. 13). That is, the first filler 222 may overlap the camera, in the plan view. Since the first region 102 may be a light transmission region, light passing through the opening formed in the first region 102 may be incident on the camera 300.

In the plan view, the second filler 224 may overlap the second region 104. A light transmittance of the second region 104 may be less than a light transmittance of the first region 102. The second region 104 may overlap the light emitting element LD. Since the light may be emitted from the light emitting element LD, a light efficiency may be improved even if the refractive index of the second filler 224 is lower than that of the first filler 222. Accordingly, the refractive index of the second filler 224 may be less than the refractive index of the first filler 222. Stated another way, the refractive index of the first filler 222 may be greater than the refractive index of the second filler 224.

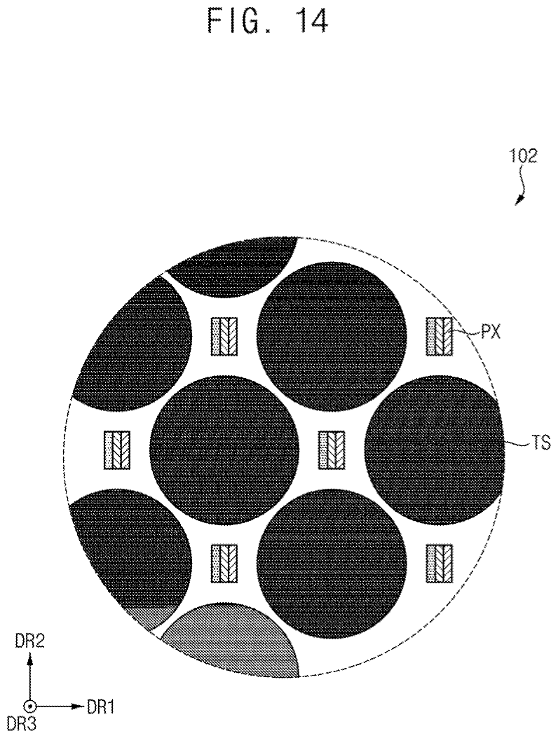

The refractive index of the first filler 222 and the refractive index of the second filler 224 may be different from each other. For example, the refractive index of the first filler 222 may be between about 1.48 and about 1.52. A refractive index of the second substrate 200 and a refractive index of the camera lens (e.g., camera lens TS of FIG. 14) may be about 1.5. That is, the difference between the refractive index of the first filler 222 and a refractive index of the camera lens TS may be less than or equal to about 0.2. Further, the difference between the refractive index of the second substrate 200 and the refractive index of the camera lens TS may be less than or equal to about 0.2.

When the refractive index of the first filler 222 exceeds about 1.52, multi reflection interference (MRI), due to an optical path difference, may be increased. That is, as light travels through materials having different refractive indexes, an optical path of the light may change. This change in the optical path, or the optical path difference, may cause images, displayed or captured, to become blurry.

When the refractive index of the first filler 222 is less than about 1.48, the MRI may be increased, similar to the case where the refractive index of the first filler 222 exceeds about 1.52. That is, blurring of images due to multiple diffractions may be caused below and above a range of refractive indexes between about 1.48 and about 1.52 in a case where the refractive index of the second substrate 200 and a refractive index of the camera lens (e.g., camera lens TS of FIG. 14) may be about 1.5.

TABLE 1

| Refractive Index | MRI (%) |
|---|---|
| 1.47 | 0.4 |
| 1.50 | 0.2 |
| 1.53 | 1.1 |

Table 1 shows multiple diffraction levels (MRI) measurements after filling the filler layer 220 with fillers having various refractive indices (e.g., the first filler 222 or the second filler 224). As summarized in Table 1, when the fillers having a refractive index of about 1.50 are used, the MRI has a smallest value (about 0.2%). On the other hand, when the filler having refractive index of about 1.47 or about 1.53 is used, the respective MRIs are increased by about 0.4% and about 1.1%. That is, when the fillers having the refractive index of less than about 1.48 or more than about 1.52 are used, the blurring of images may occur due to multiple diffractions. Accordingly, by using the first filler 222 having the refractive index between about 1.48 and about 1.52, the occurrence of blurred images due to the optical path difference may be prevented.

The refractive index of the second filler 224 may be less than the first filler 222. For example, the refractive index of the second filler 224 may be less than or equal to about 1.45. Preferably, the refractive index of the second filler 224 may be between about 1.40 and about 1.45.

When the refractive index of the second filler 224 exceeds about 1.45, a light efficiency may be decreased compared to the case where the filler layer 220 is not used (e.g., only an air gap is used).

TABLE 2

| Refractive Index | Light Efficiency (%) |
|---|---|
| 1.50 | 88.0 |
| 1.47 | 88.8 |
| 1.45 | 89.3 |
| 1.44 | 89.2 |

Table 2 shows light efficiency of the display device 1000 having the filler layer 220, as compared to when the filler layer 220 is not present. As summarized in Table 2, when the fillers having the refractive index of about 1.45 are used, the light efficiency is about 89.3%. On the other hand, when the filler having the refractive index of about 1.47 is used, the light efficiency is about 88.8%, and when the filler having the refractive index of about 1.50 is, the light efficiency is about 88.0%. That is, the light efficiency may be decreased as the refractive index of the filler increases. On the other hand, when the filler having the refractive index of about 1.44 is used, the light efficiency is about 89.2%. That is, when the refractive index of the filler is less than or equal to about 1.45, the decrease in light efficiency may be reduced, and the occurrence of blurring of images due to an optical path difference may be prevented. Therefore, by using the second filler 224 having a refractive index of less than about 1.45, the decrease in light efficiency may be reduced, and the occurrence of blurring of images due to an optical path difference may be prevented at the same time.

The first filler 222 and the second filler 224 may include different materials. In this case, to reduce haze due to the use of different material, the first filler 222 and the second filler 224 may include similar materials. Here, the haze may be understood as an image quality degradation problem caused by diffusion of external light reflected from the display panel by the camera lens (e.g., the camera lens TS of FIG. 14).

Each of the first filler 222 and the second filler 224 may include a silicon (Si) based material. Each of the first filler 222 and the second filler 224 may be formed by at least one of a jet dispenser method, an inkjet method, or a one drop filling (ODF) method, or the like. A silicon (Si) based material may not damage the capping layer 310 disposed under the first filler 222 and the second filler 224. For example, the capping layer 310 may be damaged in a case where the first filler 222 and the second filler 224 chemically penetrate the capping layer 310, where the first filler 222 and the second filler 224 abrade the capping layer 310, or the like. To substantially prevent these problems, the first filler 222 and the second filler 224 may include the silicon (Si) based material that may not damage the capping layer 310.

In an embodiment, the first filler 222 may include a siloxane backbone, and the siloxane backbone may be connected to at least one phenyl group. The first filler 222 may be a compound represented by chemical formulas 1 and 2 below. However, a molecular shape of the first filler 222 may not be limited to the following examples.

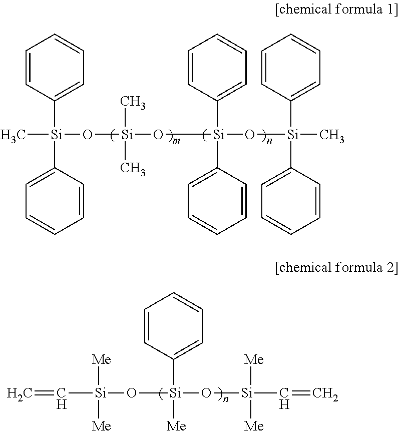

In an embodiment, the second filler 224 may include a siloxane backbone, and the siloxane backbone may be connected to at least one methyl group. The second filler 224 may be a compound represented by chemical formulas 3 and 4 below. However, a molecular shape of the second filler 224 may not be limited to the following examples.

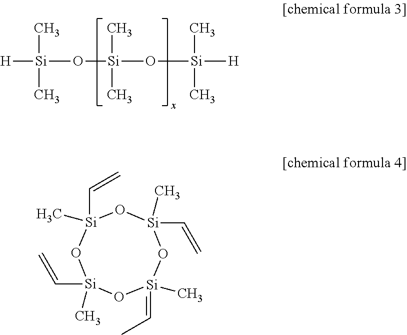

Referring back to FIGS. 2 and 3, the cell seal 212 may serve to protect a side surface between the first substrate 100 and the second substrate 200. The cell seal 212 may be referred to as a frit. The cell seal 212 may include a main material such as a glass raw material in powder form, a silicon oxide, and the like. For example, the cell seal 212 may be in a paste state including a silicon oxide, a laser or infrared ray absorber, an organic binder, a filler for reducing a thermal expansion coefficient, and the like. The cell seal 212 in the paste state may be cured while the organic binder and moisture are removed after drying or firing. The laser or infrared ray absorber may include a transition metal compound.

The second substrate 200 may be disposed on the filler layer 220. The second substrate 200 may prevent penetration of moisture and oxygen into the display element layer 210 (e.g., see FIG. 4) of the first substrate 100 from the outside.

In an embodiment, the second substrate 200 may have a multi-layer structure. For example, the second substrate 200 may have a structure in which a first inorganic encapsulation layer, an organic encapsulation layer, and a second inorganic encapsulation layer are sequentially stacked. Alternatively, the second substrate 200 may have a mono-layer structure. For example, the second substrate 200 may include glass.

A polarization layer capable of selectively transmitting light emitted from the display element layer 210, a resin layer capable of filling an opening overlapping the first region 102, a window capable of protecting lower structures and allowing external light to enter the camera (e.g., the camera 300 of FIG. 13), and an adhesive layer capable of bonding the window to the lower structures may be disposed on the second substrate 200.

In the above, it has been described that the first substrate 100 and the camera 300 may be located on a same line in a cross-sectional view, but the present disclosure may not be limited thereto. The camera 300 may be disposed under the first substrate 100. The camera 300 may be disposed partially overlap the first substrate 100 in the cross-sectional view.

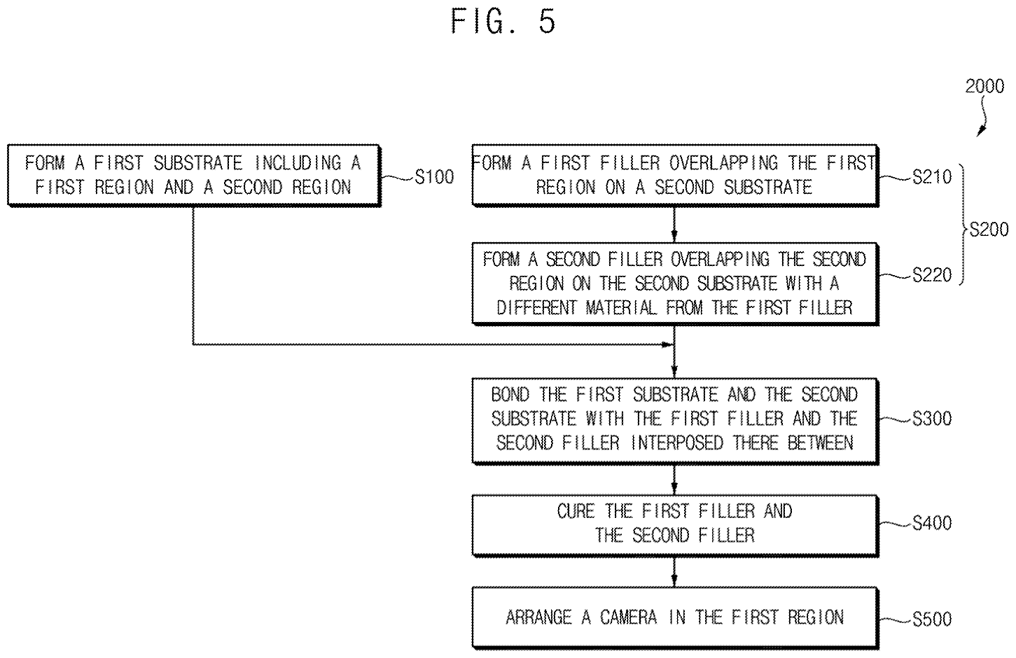

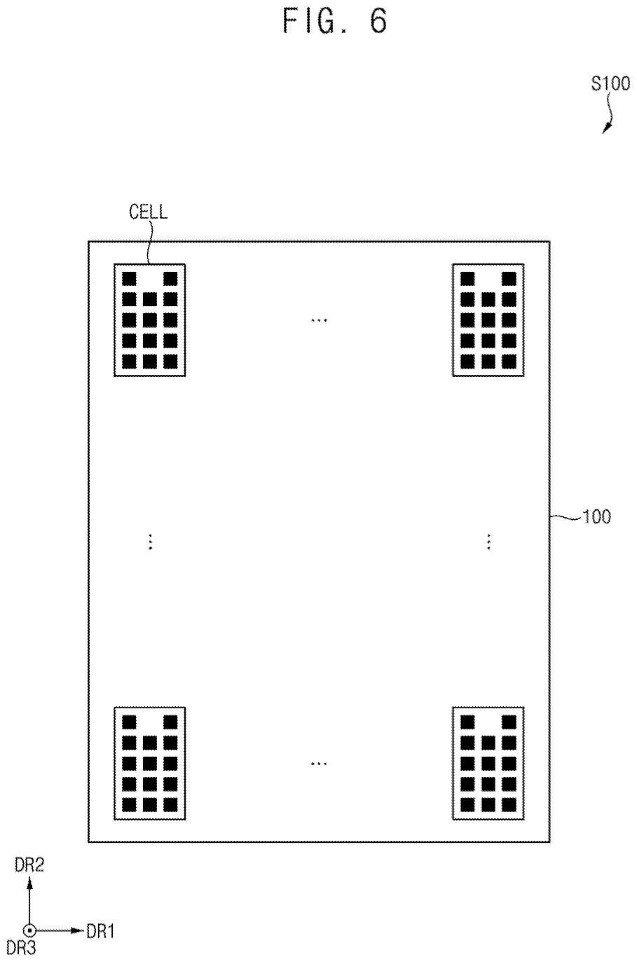

FIG. 5 is a flowchart of a method of manufacturing the display device according to an embodiment of the present disclosure, and FIGS. 6, 7, 8, 9, 10, 11, 12, and 13 are views for illustrating the method of manufacturing the display device of FIG. 5.

Referring to FIG. 5, the method 2000 of manufacturing the display device according to embodiments of the present disclosure may include forming the first substrate 100 (S100), forming the first filler 222 and the second filler 224 on the second substrate 200 (S200), bonding the first substrate 100 and the second substrate 200 (S300), curing the first filler 222 and the second filler 224 (S400), and arranging the camera 300 in the first region 102 (S500).

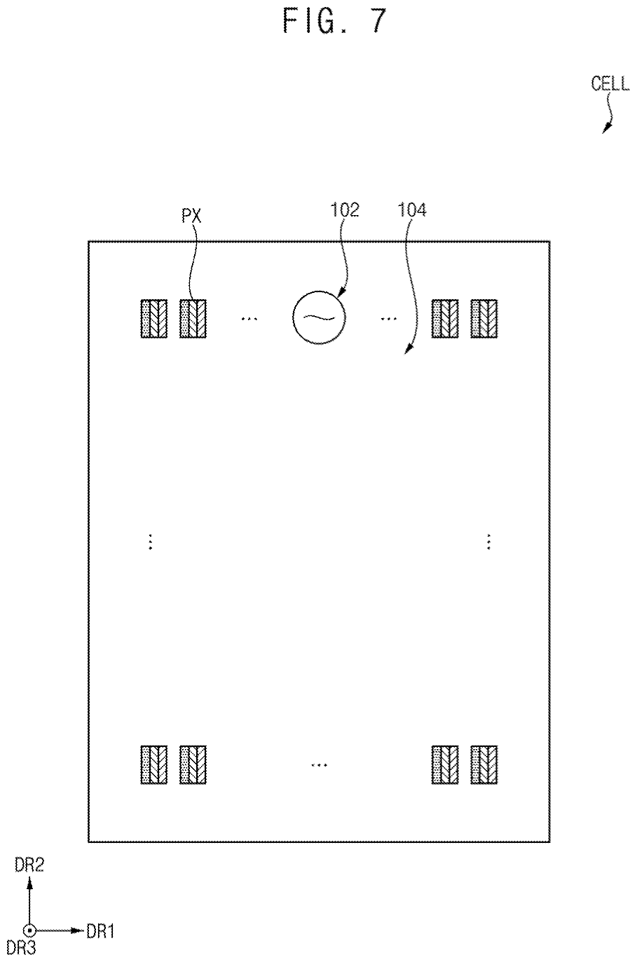

Referring to FIGS. 6 and 7, the first substrate 100 including the first region 102 and the second region 104 may be formed (S100).

The first substrate 100 may include a plurality of cells. Each of the plurality of cells may include the first region 102 and the second region 104. A hole may be formed in the first region 102. The hole may be a space where the camera 300 may be disposed. The second region 104 may surround the first region 102 in the plan view. The plurality of pixels PX may be disposed in the second region 104.

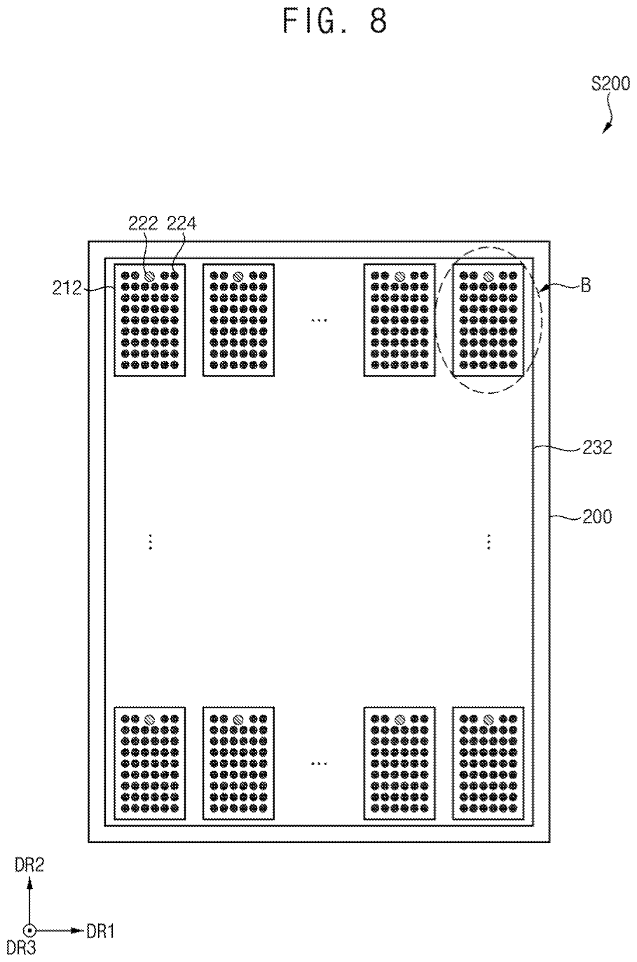

Referring to FIGS. 8, 9, and 10, the first filler 222 and the second filler 224 may be formed on the second substrate 200 (S200).

As shown in FIG. 8, the cell seal 212 may be applied on the second substrate 200. The cell seal 212 may be applied to a position corresponding to each of the plurality of cells. For example, the cell seal 212 may be applied surrounding each of the plurality of cells. A mother-glass seal 232 may be applied.

As described above with reference to FIGS. 2, 3, and 4, the cell seal 212 may be an adhesive applied to protect the side surface between the first substrate 100 and the second substrate 200.

The mother-glass seal 232 may be an adhesive applied to bond the first substrate 100 and the second substrate 200 together. The mother-glass seal 232 may include an organic adhesive or the like that may be cured by ultraviolet light.

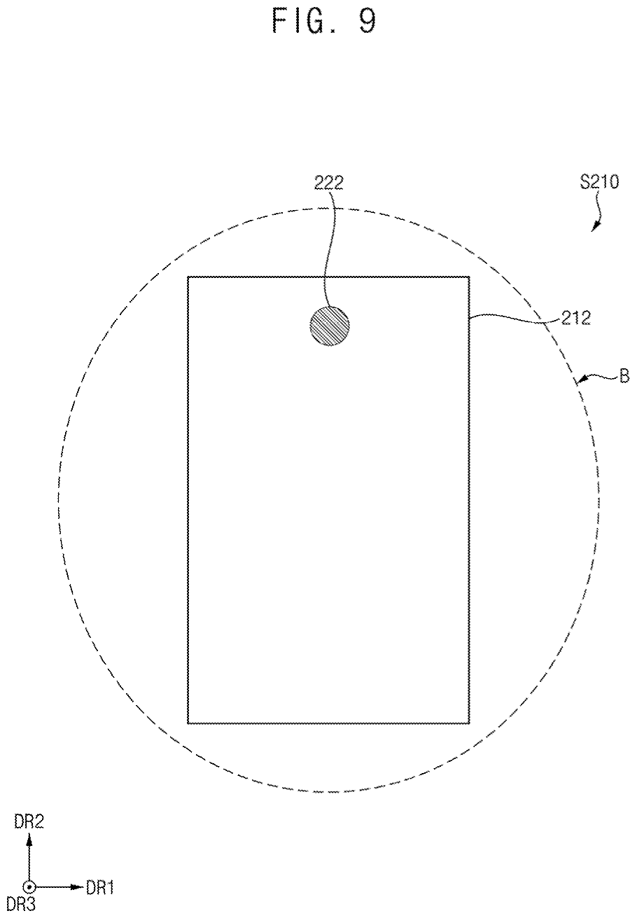

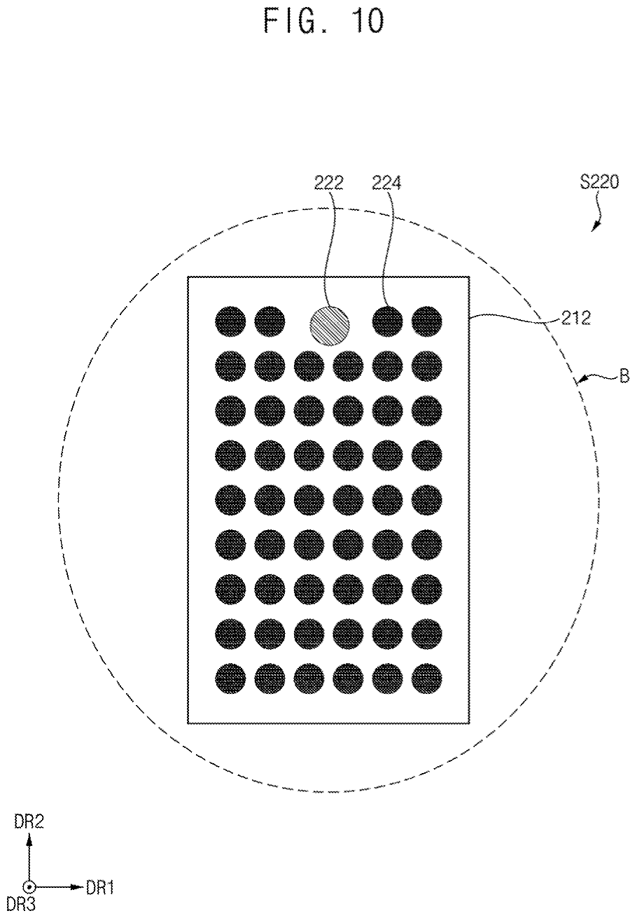

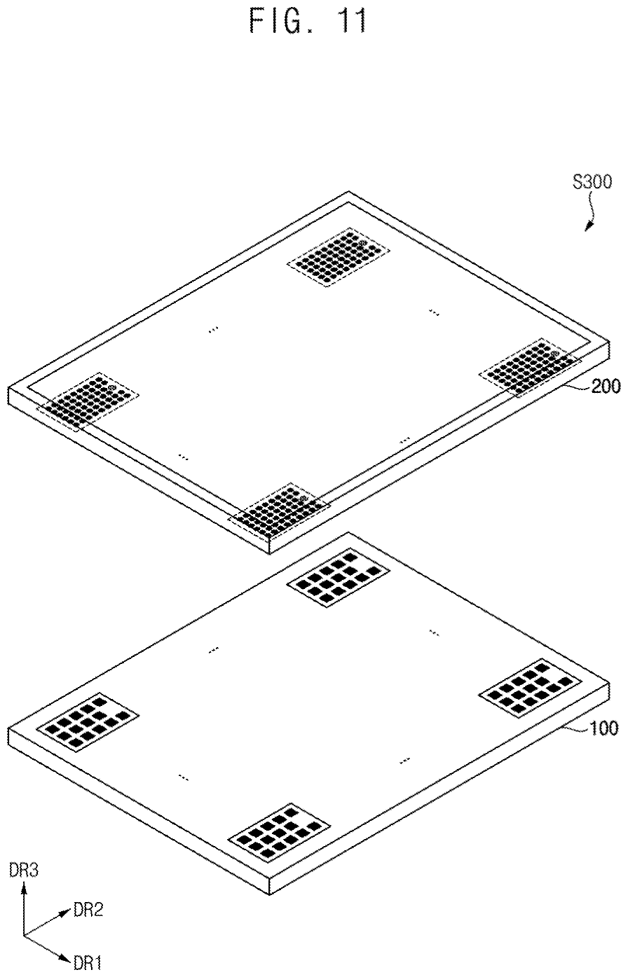

After the cell seal 212 is applied, the filler layer 220 may be formed on the second substrate 200 before the mother-glass seal 232 is applied. Hereinafter, a process of forming the filler layer 220 will be described specifically with reference to FIGS. 9 and 10.

As shown in FIG. 9, the first filler 222 overlapping the first region 102 may be formed on the second substrate 200 (S210). The second substrate 200 may face the first substrate 100 as shown in FIG. 11, and the first region 102 may overlap the camera 300.

As described above with reference to FIGS. 2, 3, and 4, the refractive index of the first filler 222 may be between about 1.48 and about 1.52. Accordingly, compared to the case where the filler layer 220 is not used (e.g., only the air gap is used), the occurrence of blurring of images due to the multiple diffractions may be prevented.

As shown in FIG. 10, the second filler 224 overlapping the second region 104 may be formed on the second substrate 200 (S220). The second region 104 may overlap the light emitting element LD.

As described above with reference to FIGS. 2, 3, and 4, the refractive index of the first filler 222 may be less than or equal to about 1.45. Accordingly, the decrease in light efficiency may be reduced.

The forming of the first filler 222 (S210) and the forming of the second filler 224 (S220) may be separately performed. After the forming of the first filler 222, the second filler 224 may be formed, or the order may be changed.

The first filler 222 may be disposed in the first region 102, and the second filler 224 having a refractive index less than a refractive index of the first filler 222 may be disposed in the second region 104. The first region 102 may overlap the camera 300 and the second region 104 may overlap the light emitting element (e.g., the light emitting element LD of FIG. 4). The blurring of images caused by an optical path difference may be improved by matching the refractive index of the camera lens (e.g., the camera lens TS of FIG. 14) and the refractive index of the first filler 222. The second filler 224 having a refractive index less than a refractive index of the first filler 222 may reduce a decrease in light efficiency of the display device 1000, and further the refractive index of the second filler 224 may reduce or prevent the blurring of images due to an optical path difference.

In this case, haze may occur in the display device 1000 as different fillers (e.g., the first filler 222 and the second filler 224) are used. To prevent this, the first filler 222 and the second filler 224 may include similar materials. That is, each of the first filler 222 and the second filler 224 may include a silicon (Si) material. For example, the first filler 222 may include the siloxane backbone, and the siloxane backbone may be connected to at least one phenyl group, and the second filler 224 may include the siloxane backbone, and the siloxane backbone may be connected to at least one methyl group.

As shown in FIG. 10, the first filler 222 and the second filler 224 may be formed on the same layer. The forming of the first filler 222 and the second filler 224 may be formed by various known methods. For example, the first filler 222 and the second filler 224 may be formed by at least one of the jet dispenser method, the inkjet method, or the one drop filling (ODF) method, or the like.

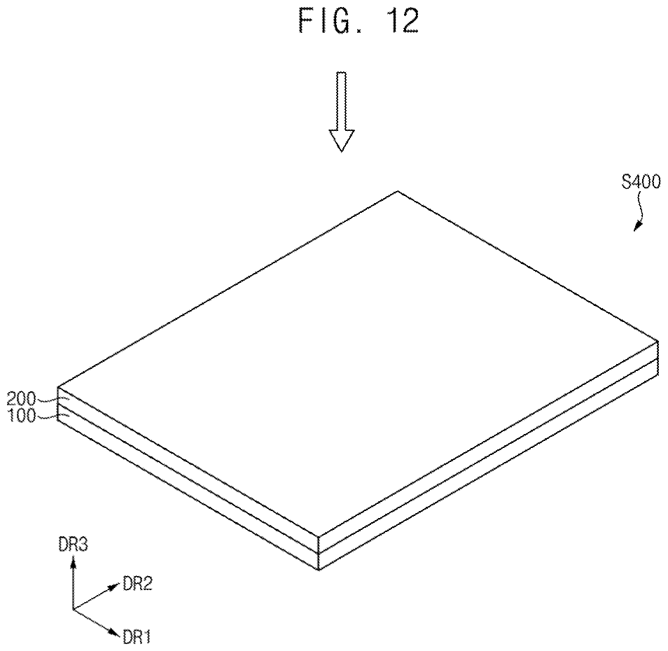

Referring to FIGS. 11 and 12, after bonding the first substrate 100 and the second substrate 200 (S300), the first filler 222 and the second filler 224 may be cured (S400).

The first substrate 100 and the second substrate 200 may be bonded with the first filler 222 and the second filler 224 interposed therebetween. After that, the first filler 222 and the second filler 224 may be cured. The first filler 222 and the second filler 224 may be cured by at least one of a thermal curing method, or an ultraviolet (UV) curing method, or the like. These may be used individually or in combination with each other. The curing (S400) of the first filler 222 and the second filler 224 may use platinum (Pt) as a catalyst. In the case of the thermal curing, a temperature of the thermal curing may be less than or equal to about 100° C.

Referring to FIG. 13, the camera 300 may be arranged to overlap the first region 102 (S500). That is, the first filler 222 and the camera 300 may overlap, in the plan view.

In the above, it has been described that the first substrate 100 and the camera 300 may be positioned on the same line in the cross-sectional view, but the present disclosure may not be limited thereto.

FIG. 14 is a view for illustrating a display device according to another embodiment of the present disclosure. For example, FIG. 14 may be an enlarged plan view of the first region 102 of FIG. 1. Redundant descriptions of the same components described above with reference to FIGS. 1, 2, 3, and 4 may be omitted or simplified.

Referring to FIGS. 1, 2, 3 and 14, the display device 1000 may include the first substrate 100 including the first region 102 and the second region 104, the filler layer 220 disposed on the first substrate 100, and the second substrate 200 disposed on the filler layer 220.

In FIG. 14, the camera lens TS and the plurality of pixels PX may be disposed in the first region 102, in the plan view. That is, the first region 102 may include a pixel area in which the plurality of pixels PX may be disposed and the transmission area in which the plurality of pixels PX may not be disposed. The transmission area may overlap the camera lens TS in the plan view. The transmission area may be a light transmittable area. Light passing through the transmission area may be incident on the camera lens TS. As described above, for refractive index matching with the camera lens TS, the refractive index of the first filler 222 may be between about 1.48 and about 1.52. The first filler 222 may be disposed to overlap the first region 102.

The plurality of pixels PX may be disposed in the second region 104. As described above, the second filler 224 may have a refractive index of less than or equal to about 1.45, and may be disposed to overlap the second region 104 in order to match the refractive indices of the second substrate 200 and the filler layer 220, and at the same time reduce the decrease in light efficiency.

The display device and the method of manufacturing the same according to some embodiments may be applied to an electrical device including a display device. For example, embodiments of the present disclosure may be applied to display apparatuses.

Embodiments of the present disclosure may be applied to electronic devices including the display device. For example, embodiments of the present disclosure may be applied to various electronic devices such as display devices for vehicles, ships, and aircraft, portable communication devices, display devices for display or information transmission, and medical display devices.

The foregoing is illustrative of embodiments of the present disclosure and is not to be construed as limiting thereof. Although exemplary embodiments of the present disclosure have been described, those skilled in the art will readily appreciate that many modifications are possible without materially departing from the novel teachings and advantages of the present disclosure. Accordingly, all such modifications are intended to be included within the scope of the present disclosure as defined in the claims.

What is claimed is:

1. A display device comprising:
a first substrate including a first region and a second region surrounding the first region in a plan view;
a first filler disposed on the first substrate and overlapping the first region;
a second filler disposed on the first substrate and overlapping the second region, and including a material different from the first filler; and
a second substrate disposed on the first filler and the second filler.

2. The display device of claim 1, wherein a refractive index of the first filler and a refractive index of the second filler are different from each other.

3. The display device of claim 1, wherein a refractive index of the first filler is greater than a refractive index of the second filler.

4. The display device of claim 1, wherein a refractive index of the first filler is between about 1.48 and about 1.52.

5. The display device of claim 4, wherein a refractive index of the second filler is less than about 1.45.

6. The display device of claim 1, further comprising:
a camera overlapping the first region and the first filler.

7. The display device of claim 1, wherein the first filler includes a siloxane backbone, and the siloxane backbone is connected to at least one phenyl group.

8. The display device of claim 1, wherein the second filler includes a siloxane backbone, and the siloxane backbone is connected to at least one methyl group.

9. A display device comprising:
a first substrate including a light emitting element, a first region and a second region surrounding the first region;
a camera overlapping the first region in a plan view;
a filler layer disposed on the first substrate, including a first filler overlapping the first region, and a second filler overlapping the second region and having a refractive index less than a refractive index of the first filler; and
a second substrate disposed on the filler layer.

10. The display device of claim 9, wherein a difference between the refractive index of the first filler and the refractive index of the second filler is less than or equal to about 0.2, and
wherein a difference between the refractive index of the first filler and a refractive index of a lens of the camera is less than or equal to about 0.2.

11. The display device of claim 9, wherein the first filler overlaps the camera in the plan view.

12. The display device of claim 11, wherein the refractive index of the second filler is less than or equal to about 1.45.

13. The display device of claim 9, wherein a light transmittance of the second region is less than a light transmittance of the first region.

14. A method of manufacturing a display device, the method comprising:
forming a first substrate including a first region and a second region surrounding the first region in a plan view;
forming a first filler, overlapping the first region, on a second substrate facing the first substrate; and
forming a second filler, overlapping the second region, on the second substrate and formed of a material different from the first filler.

15. The method of claim 14, wherein the first filler is formed by at least one of a jet dispenser method, an inkjet method, or a one drop filling method, and wherein the second filler is formed by at least one of the jet dispenser method, the inkjet method, or the one drop filling method.

16. The method of claim 14, wherein the forming of the first filler and the forming of the second filler are separately performed.

17. The method of claim 14, further comprising:
bonding the first substrate and the second substrate with the first filler and the second filler interposed therebetween; and
curing the first filler and the second filler.

18. The method of claim 17, wherein the first filler and the second filler are cured by one of a thermal curing method, an ultraviolet (UV) curing method, and a thermal and UV curing method.

19. The method of claim 18, wherein a temperature of the thermal curing method is less than or equal to about 100° C.

20. The method of claim 17, further comprising:
arranging a camera in the first region.
